(19) United States
(12) Patent Application Publication
(10) Pub. No.: US 2011/0234284 A1
(43) Pub. Date: Sep. 29, 2011

(54) SEMICONDUCTOR BOOST CIRCUIT AND METHOD OF CONTROLLING THE SAME

(75) Inventor: Masaaki KUWAGATA, Yokohama-Shi (JP)

(73) Assignee: Kabushiki Kaisha Toshiba, Tokyo (JP)

(21) Appl. No.: 13/053,778

(22) Filed: Mar. 22, 2011

(30) Foreign Application Priority Data
Mar. 25, 2010 (JP) 2010-070629

(51) Int. Cl. H03K 3/00

(52) U.S. Cl. 327/291

(57) ABSTRACT

According to one embodiment, provided is a semiconductor boost circuit including a pump circuit, a switch signal generating circuit and a clock signal generating circuit. The pump circuit receives a clock signal and performs charge pump operation on the basis of the clock signal to boost an input potential to a set potential. The switch signal generating circuit outputs CLK cycle switch signal when a potential output by the pump circuit reaches a first potential greater than the input potential and less than the set potential. The clock signal generating circuit outputs the clock signal having a first frequency if not receiving the CLK cycle switch signal, and, on the other hand, outputs the clock signal having a second frequency greater than the first frequency if receiving the CLK cycle switch signal.

### CROSS-REFERENCE TO RELATED APPLICATIONS

This application is based upon and claims the benefit of priority from the prior Japanese Patent Application No. 2010-70629, filed on Mar. 25, 2010, the entire contents of which are incorporated herein by reference.

### FIELD

Embodiments described herein relate generally to a semiconductor boost circuit and a method of controlling the same.

### BACKGROUND

In an EEPROM (electrically erasable and programmable read only memory), such as a NAND flash memory, when various memory operations (read operation, program operation, erase operation and the like) are performed, a voltage higher than that of an external power supply needs to be supplied to a memory cell array. A boost circuit provided in a NAND flash memory supplies this high voltage. As such a boost circuit, a charge pump circuit (hereinafter referred to simply as a “pump circuit”) including MOS transistors connected in series and capacitors connected to nodes between the MOS transistors is typically used (e.g., see Japanese Patent Application Laid-Open No. 2009-141218).

Traditionally, a boost circuit aimed at reduction in power consumption has been disclosed (Japanese Patent Application Laid-Open No. 1999-328973). With the boost circuit, the oscillation period of a ring oscillator is shortened during voltage boosting, and is lengthened after the boosting has been completed.

### BRIEF DESCRIPTION OF THE DRAWINGS

FIG. 1 is a block diagram illustrating part of a configuration of a NAND flash memory;

FIG. 2 is a circuit diagram illustrating an exemplary pump circuit;

FIG. 3 schematically illustrates a relationship of current consumption of the pump circuit and a frequency of a clock signal input to the pump circuit;

FIG. 4(a) illustrates a simulation result of temporal waveforms of a potential output from the pump circuit, and FIG. 4(b) illustrates a simulation result of temporal waveforms of current consumption of the pump circuit;

FIG. 5 illustrates a configuration of a semiconductor boost circuit according to an embodiment of the invention;

FIG. 6 illustrates an exemplary configuration of a clock signal generating circuit;

FIG. 7 is a circuit diagram illustrating an exemplary multi-stage inverter with a delay function;

FIG. 8 illustrates temporal waveforms of a clock signal output from a clock signal generating circuit according to the embodiment of the invention;

FIG. 9(a) illustrates simulation waveforms of a potential output from a pump circuit according to the embodiment of the invention, and FIG. 9(b) illustrates simulation waveforms of current consumption of the pump circuit according to the embodiment of the invention;

FIG. 10(a) illustrates simulation waveforms of a potential output from the pump circuit according to the embodiment of the invention, and FIG. 10(b) illustrates simulation waveforms of current consumption of the pump circuit according to the embodiment of the invention;

FIG. 11 illustrates a configuration of a semiconductor boost circuit according to a modification of the embodiment of the invention;

FIG. 12 illustrates a configuration of a semiconductor boost circuit according to another modification of the embodiment of the invention; and

FIG. 13 is a time chart for illustrating operation of the pump circuit.

### DETAILED DESCRIPTION

According to one embodiment, there is provided a semiconductor boost circuit including a pump circuit, a switch signal generating circuit and a clock signal generating circuit.

The pump circuit receives a clock signal, and performs charge pump operation on the basis of the clock signal to boost an input potential to a set potential. The switch signal generating circuit outputs a CLK cycle switch signal when an output potential output from the pump circuit reaches a first potential which is greater than the input potential and less than the set potential. If the clock signal generating circuit does not receive a CLK cycle switch signal, it outputs a clock signal having a first frequency. On the other hand, if the clock signal generating circuit receives the CLK cycle switch signal, it outputs the clock signal having a second frequency greater than the first frequency.

Upon transition of the operating state of a NAND flash memory from the stand-by state to the active state, the pump circuit boosts a power supply voltage to supply a voltage higher than the power supply voltage to a memory cell array and a decoder circuit around it, as needed. This boosting operation of the pump circuit results in abruptly producing a large current of, for example, several 100 mA.

An abrupt increase of current in such a manner becomes the cause of fluctuations in power supply voltage and a drop in potential, and fluctuations in reference voltage and a rise in potential. As a result, there is concern about adverse effects on the operation of circuits other than the pump circuit in a memory chip and a chip set using the memory chip.

As regards current consumption of a memory, not only reducing the average current in order to decrease current consumption but also reducing the peak current in order to decrease noise is demanded. With the boost circuit disclosed in Japanese Patent Application Laid-Open No. 1999-328973 mentioned earlier, the peak of current consumption cannot be reduced, and therefore the problems described above cannot be solved.

Next, before a description of a semiconductor boost circuit according to an embodiment of the invention, a description is given of the configurations and operation of a NAND flash memory and a pump circuit.

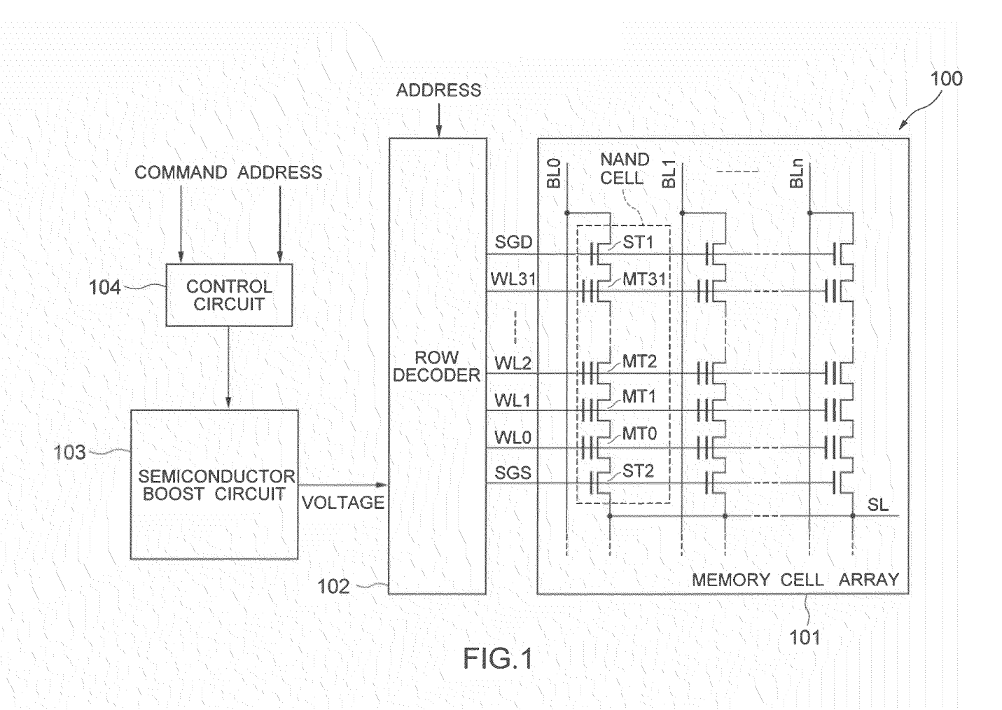

FIG. 1 is a block diagram illustrating part of a configuration of a NAND flash memory. As illustrated in FIG. 1, a NAND flash memory 100 includes a memory cell array 101, a row decoder 102, a semiconductor boost circuit 103 and a control circuit 104.

The memory cell array 101 has a plurality of NAND cells. The NAND cell is made up of memory cell transistors MT0 to MT31 connected in series and select transistors ST1 and ST2. The memory cell transistor MT is a storage element capable of holding data, and includes a stacked gate. The stacked gate includes a charge storage layer which can hold charges, and a control gate formed on the charge storage layer. The control gates of the memory cell transistors MT0 to MT31 are connected to word lines WL0 to WL31, respectively. The drain of the memory cell transistor MT31 is electrically connected through a select transistor ST1 to a bit line BL, and the source of the memory cell transistor MT0 is electrically connected through a select transistor ST2 to a source line SL.

The row decoder 102 selects a word line WL of the memory cell array 101 according to an address provided from the outside. At the time of writing data, any one of the word lines WL is selected, and then a program voltage VPGM (e.g., 20 V) is applied to the selected word line and an intermediate voltage VPASS or the like is applied to unselected word lines. At the time of reading data, any one of the word lines WL is selected, and then a read voltage VCGR is applied to the selected word line and a voltage VREAD is applied to unselected word lines. Here, both the voltages VPASS and VREAD are voltages which turn on the memory cell transistor MT regardless of whether a charge is stored in the charge storage layer. At the time of erasing data, a voltage of 0 V is applied to all the word lines WL, and a high voltage (e.g., 20 V) is applied to a well region in which the memory cell array 101 is formed.

The semiconductor boost circuit 103 includes a pump circuit configured to boost a power supply voltage to a desired voltage, and supplies a required voltage to the row decoder 102.

The control circuit 104 receives an address and a command from the outside. Then, the control circuit 104 controls the semiconductor boost circuit 103 according to the received command and address, and instructs the semiconductor boost circuit 103 to produce a required voltage.

Next, a description is given of the configuration and operation of a pump circuit provided in the semiconductor boost circuit 103 mentioned above.

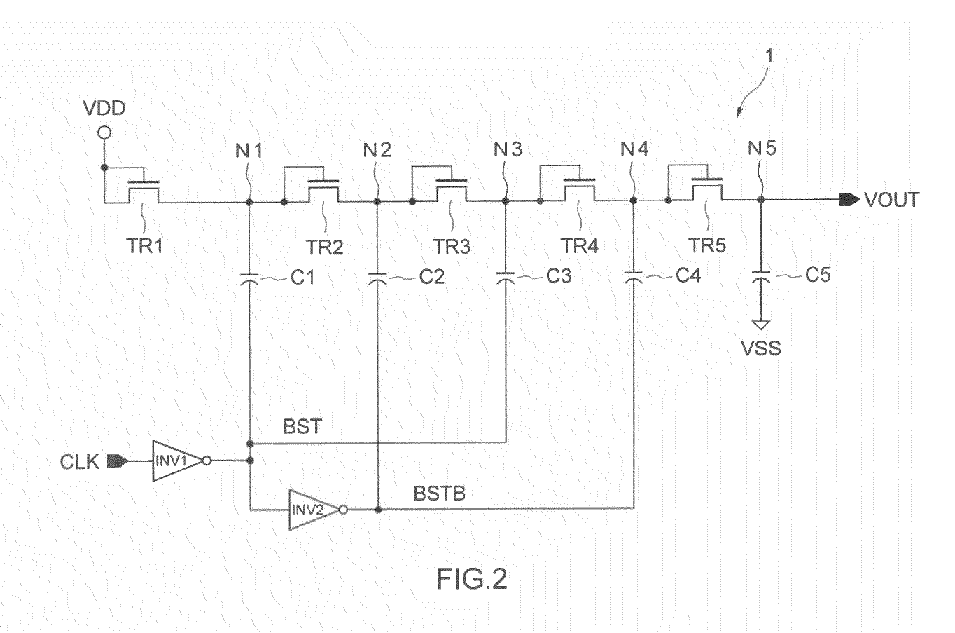

FIG. 2 illustrates an exemplary circuit diagram of a pump circuit 1. As illustrated in FIG. 2, the pump circuit 1 includes MOS transistors TR1 to TR5, capacitors (capacitive elements) C1 to C5 and inverters INV1 and INV2. Here, n-channel MOS transistors are used as the MOS transistors TR1 to TR5. The MOS transistors TR1, TR2, . . . , TR5 are each in a diode-connected configuration where the drain and the gate are connected together, and operate as rectifying devices. It is to be noted that the number of MOS transistors and the number of capacitors are not limited to those mentioned above.

As can be seen from FIG. 2, the MOS transistors TR1, TR2, . . . , TR5 are connected in series. To be more specific, the drain of the MOS transistor TR1 is connected to a power supply potential VDD, the source is connected through a node N1 to the drain of the MOS transistor TR2. Hereinbelow, likewise, the source of the MOS transistor TR2 is connected through a node N2 to the drain of the MOS transistor TR3. The source of the MOS transistor TR3 is connected through a node N3 to the drain of the MOS transistor TR4. The source of the MOS transistor TR4 is connected through a node N4 to the drain of the MOS transistor TR5. The source of the MOS transistor TR5 is connected through a node N5 to an output terminal V_{OUT} of the pump circuit 1.

As can also be seen from FIG. 2, one ends of the capacitors C1, C2, C3, C4 and C5 are connected to the nodes N1, N2, N3, N4 and N5, respectively. Further, the other ends of the capacitors C1 and C3 are connected to an output end of the inverter INV1, and the other ends of the capacitors C2 and C4 are connected to an output end of the inverter INV2. The other end of the capacitor C5 is connected to a ground potential VSS.

The inverter INV1 is connected to a CLK terminal which receives a clock signal, and outputs a BST (boost) signal. The inverter INV2 is connected to the output end of the inverter INV1 and outputs a BSTB signal which is an inverted signal of the BST signal. That is, the BST signal and the BSTB signal are a so-called two-phase clock in which their generation timings do not overlap with each other.

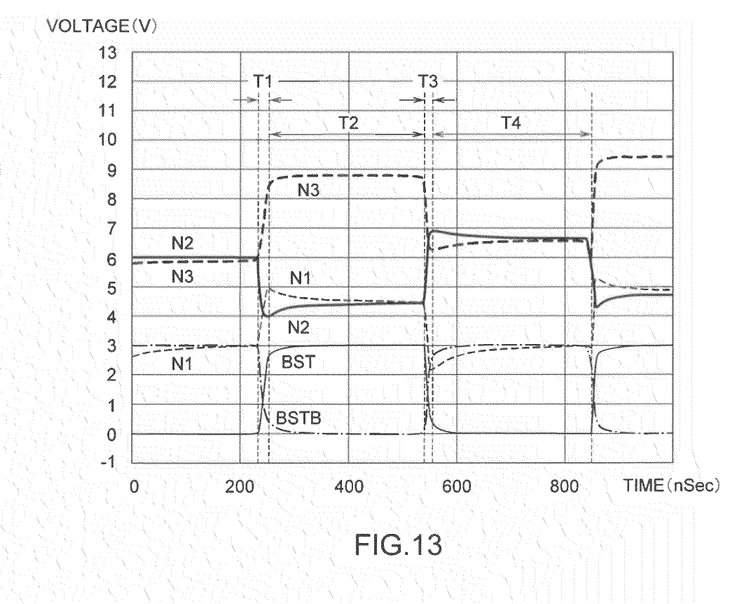

Next, with reference to FIG. 13, the operation of the pump circuit 1 in the above-mentioned configuration is described. FIG. 13 illustrates exemplary operation waveforms of the pump circuit 1.

As described above, according to clock signals received by the pump circuit 1, the BST signal and the BSTB signal change alternately from a High level to a Low level and from the Low level to the High level such that the BST signal and the BSTB signal do not overlap each other. In the example illustrated in FIG. 13, the High level of the BST and BSTB signals is 3 V of the power supply voltage, and the Low level is 0 V of a reference voltage.

As illustrated in FIG. 13, in a time period T1, the BST signal shifts from the Low level to the High level, and the BSTB signal shifts from the High level to the Low level. Then, with the rise of the BST signal, the potential at one end of the capacitor C1 rises, and, due to capacitive coupling, the potential at the node N1 rises. Likewise, the potential at one end of the capacitor C3 rises, and, as a result, the potential at the node N3 rises. On the other hand, the potential at one end of the capacitor C2 drops, and, due to capacitive coupling, the voltage at the node N2 falls. Accordingly, as can be seen from FIG. 13, immediately after the lapse of the time period T1, the potential at the node N1 is greater than the potential at the node N2 (V_{N1}>V_{N2}). For this reason, in a time period T2, a current flows from the node N1 to the node N2. As can be seen from FIG. 13, the potential at the node N1 gradually falls, and conversely the potential at the node N2 gradually rises. In the case where the threshold voltages of the MOS transistors TR2 to TR5 are set to about 0 V, if the time period T2 is sufficiently long, the node N2 is charged until the potential at the node N1 and the potential at the node N2 become nearly equal. It is to be noted that, in this period, no current flows from the node N3 toward the node N2 although the potential at the node N3 is greater than the potential at the node N2 (V_{N3}>V_{N2}). This is because the diode-connected MOS transistor TR3 functions as a rectifying device, and no reverse current flows.

Subsequently, as illustrated in FIG. 13, in a time period T3, the BST signal shifts from the High level to the Low level, and the BSTB signal shifts from the Low level to the High level. Then, due to capacitive coupling, the potentials at the node N1 and the node N3 fall, and the potential at the node N2 rises. For this reason, in a time period T4, the node N1 is charged through the MOS transistor TR1 from the power supply VDD, and the node N3 is charged through the MOS transistor TR2 from the node N2.

As described above, in the time period T2, a current flows from the node N1 to the node N2, and flows from the node N3 to the node N4. On the other hand, in the period T4, a current flows from the power supply VDD to the node N1, and flows from the node N2 to the node N3.

The node N3 and the node N4 as well as the node N4 and the node N5 operate in the same manner as mentioned above. Thus, a current flows from the side of the power supply VDD to the side of an output terminal VOUT.

By repeating a series of operations from the time period T1 to the time period T4, the pump circuit 1 charges the output terminal VOUT (node N5) to raise the output potential.

In the case where the potential of the output terminal VOUT is low, the potential difference between the node N1 and the node N2 immediately after the time period T1 is large, and therefore the current flowing in the time period T2 is relatively large. Thereafter, when the output terminal VOUT is charged, the potential difference between the node N1 and the node N2 immediately after the time period T1 is small compared to the case in which the output potential is low. Thus, the current flowing from the node N1 to the node N2 in the time period T2 becomes smaller as the output potential rises. This occurs not only between the node N1 and the node N2, but also similarly between other nodes, that is, between the power supply VDD and the node N1, between the node N2 and the node N3, between the node N3 and the node N4, and between the node N4 and the node N5 (VOUT). Accordingly, as charging of the output terminal VOUT (the node N5) progresses, the output current falls. That is, a current flowing from the power supply VDD through the nodes N1, N2, N3 and N4 to the output terminal OUT decreases. As a result, as the charging of the output terminal VOUT progresses, current consumption deceases.

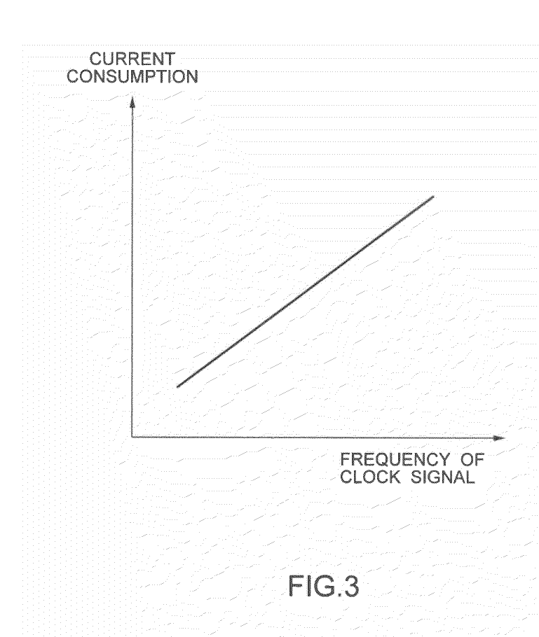

FIG. 3 schematically illustrates a relationship between current consumption of the pump circuit and the frequency of a clock signal input to the pump circuit. As illustrated in FIG. 3, when the frequency of the clock signal is raised, current consumption increases roughly in proportion to this raise.

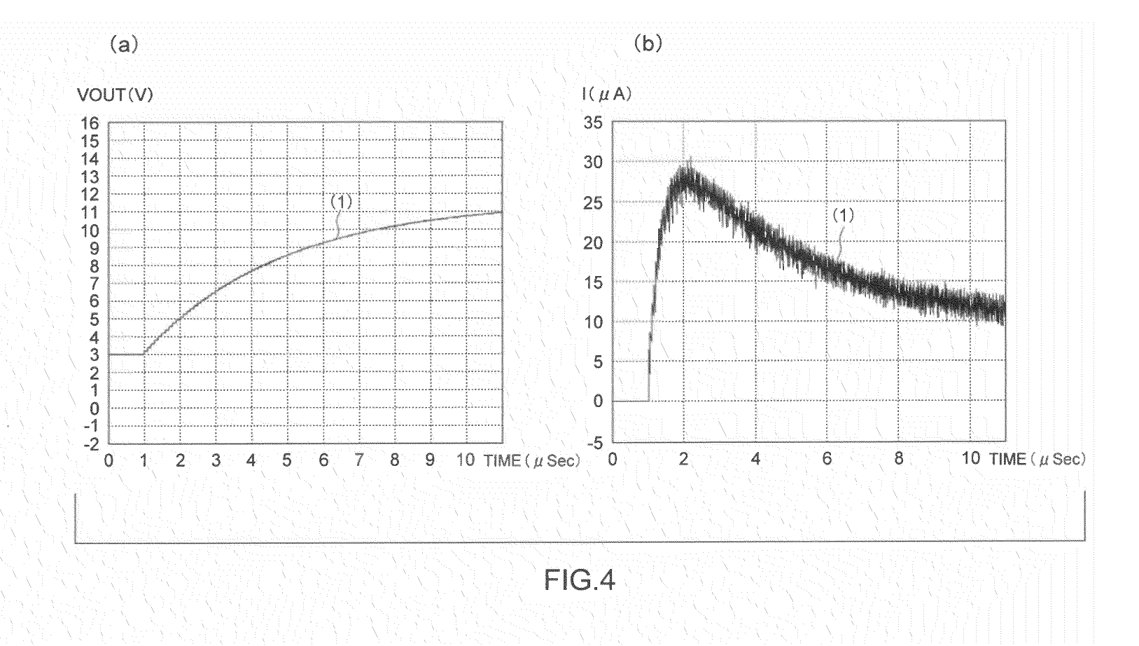

FIGS. 4(a) and 4(b) illustrate results obtained from simulating operation of the pump circuit 1. FIG. 4(a) represents temporal waveforms of the output potential VOUT of the pump circuit 1, and FIG. 4(b) represents temporal waveforms of the current consumption I of the pump circuit 1. In this simulation, it is assumed that the power supply potential VDD is 3 V, and the frequency of the clock signal is 100 ns.

As can be seen from temporal waveforms (1) of FIG. 4(b), current consumption abruptly increases immediately after the start-up of the pump circuit 1, and the current consumption reaches the peak at a time of around 2 μs. This is because the frequency of the clock signal is relatively high, the transfer efficiency of charges is good, and, in addition, the charging rate of the capacitor C5 is low at the beginning of a boosting process. After the current consumption reaches the peak, it decreases as the charging rates of the capacitors C1 to C4 of the pump circuit 1 increase.

As a result of an abrupt increase in current consumption in the boosting process in such a manner, there is a problem that, as described above, noise occurs in a power supply line, which has the possibility of causing a memory to malfunction.

The invention is made based on the technical knowledge described above. In other words, in order to solve the above-mentioned problem, the frequency of the clock signal is made small in a predetermined time period from the start of boosting. This reduces the peak value of the current consumption to suppress a sudden current change. After the lapse of a predetermined time period, the frequency of a clock signal is made large to enhance the boosting speed, so that a required boosting time is secured.

Hereinbelow, a semiconductor boost circuit according to an embodiment of the invention is described with reference to the drawings. It is to be noted that, in the drawings, elements having equivalent functions are denoted by the same reference characters, and detailed descriptions thereof will not be repeated.

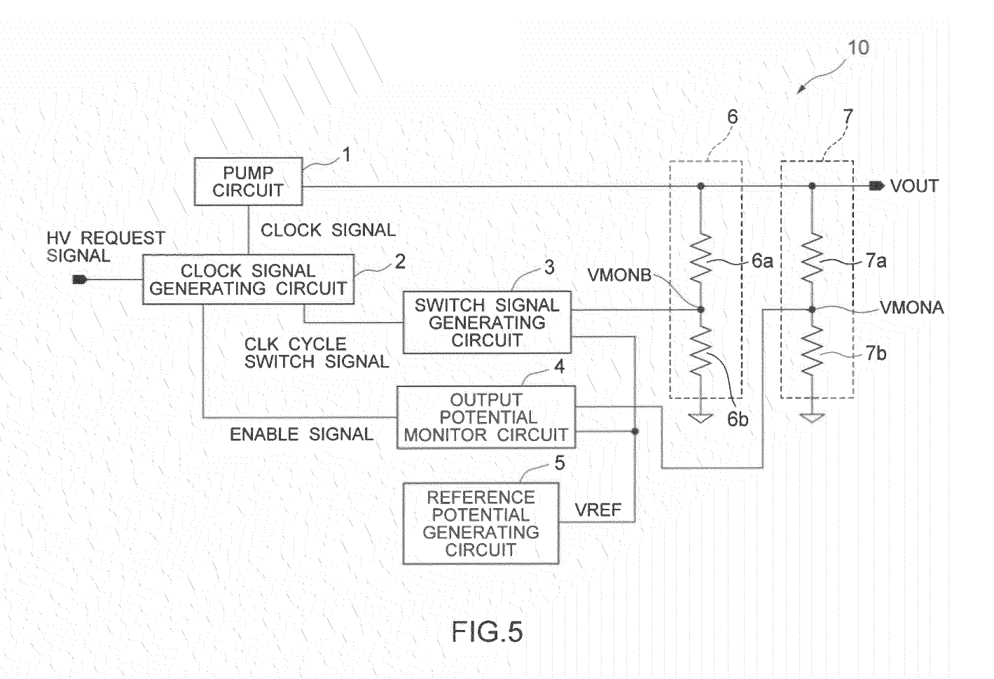

FIG. 5 illustrates a configuration of a semiconductor boost circuit 10 according to this embodiment. As can be seen from FIG. 5, the semiconductor boost circuit 10 includes the pump circuit 1, a clock signal generating circuit 2, a switch signal generating circuit 3, an output potential monitor circuit 4, a reference potential generating circuit 5 and voltage divider circuits 6 and 7.

Next, elements of the semiconductor boost circuit 10 are described.

The pump circuit 1 performs charge pump operation using a clock signal as described earlier to boost an input potential input from the external power supply to a set potential. In other words, as described in detail earlier, the pump circuit 1 has a plurality of chargeable nodes N1 to N5 connected in series through rectifying devices made of diode-connected MOS transistors. The nodes N1 to N4 are connected to one ends of the capacitors C1 to C4, respectively. Clock signals are supplied to the other ends of the capacitors C1 to C4. A clock signal is input to the capacitors C2 and C4. This clock signal is opposite in phase to a clock signal input to the capacitors C1 and C3. In synchronization with the clock signals, the pump circuit 1 sequentially transmits charges stored in the nodes N1 to N5 toward the output terminal. The pump circuit 1 outputs a voltage obtained by superimposing the voltages of the capacitors C1 to C4 on the power supply voltage.

It is to be noted that the boosting speed of the pump circuit 1 is roughly in proportion to the frequency of a clock signal input to the pump circuit as long as a frequency f of the clock signal is within the range of a frequency usually used.

The clock signal generating circuit 2 outputs a clock signal to cause the pump circuit 1 to operate. The clock signal generating circuit 2 outputs a clock signal when receiving both an HV request signal and an enable signal output from the output potential monitor circuit 4 (to be described later). Here, the HV request signal is a high potential output request signal received from the control circuit 104 described above.

In addition, the clock signal generating circuit 2 receives a CLK cycle switch signal, and changes, according to the CLK cycle switch signal, the frequency (cycle) of a clock signal to be output. In other words, the frequency (f1) of the clock signal when a CLK cycle switch signal is not received is less than the frequency (f2) of the clock signal when a CLK cycle switch signal is received (f1<f2). That is, upon receiving a CLK cycle switch signal, the clock signal generating circuit 2 increases the frequency of a clock signal to be output.

The switch signal generating circuit 3 detects whether a potential output from the pump circuit 1 reaches a predetermined potential, and outputs a CLK cycle switch signal. In more detail, the switch signal generating circuit 3 compares a monitor potential (VMONB) produced by a voltage divider circuit 6 to a reference potential (VREF) output from the reference potential generating circuit 5. If the monitor potential (VMONB) is greater than the reference potential, the switch signal generating circuit 3 assumes that the output potential of the pump circuit 1 reaches the predetermined potential, and outputs a CLK cycle switch signal to the clock signal generating circuit 2. Thus, when the output potential of the pump circuit 1 reaches the predetermined potential less than the set potential, the frequency of a clock signal output from the clock signal generating circuit 2 increases.

The output potential monitor circuit 4 is a circuit configured to detect whether a potential output from a pump circuit 1 reaches a set potential, and compares a monitor potential (VMONA) produced by a voltage divider circuit 7 to a reference potential (VREF) output from the reference potential generating circuit 5. If the monitor potential (VMONA) is less than the reference potential, the output potential monitor circuit 4 outputs an enable signal to the clock signal generating circuit 2. Conversely, if the monitor potential (VMONA) is greater than the reference potential, no enable signal is output to the clock signal generating circuit 2.

In other words, when the output potential of the pump circuit 1 reaches the set potential, the output potential monitor circuit 4 stops outputting an enable signal. As a result, the clock signal generating circuit 2 stops outputting a clock signal, so that the pump circuit 1 stops. Thereafter, when the output potential becomes less than the set potential, the output potential monitor circuit 4 outputs an enable signal. Accordingly, the clock signal generating circuit 2 outputs a clock signal, so that operation of the pump circuit 1 is resumed.

It is to be noted that the switch signal generating circuit 3 and the output potential monitor circuit 4 are composed with use of, for example, comparators.

The reference potential generating circuit 5 outputs a reference potential (VREF) to the switch signal generating circuit 3 and the output potential monitor circuit 4. It is to be noted that two reference potential generating circuits (a reference potential generating circuit A and a reference potential generating circuit B) may be provided such that a reference potential VREF1 is output from the reference potential generating circuit A to the switch signal generating circuit 3, and a reference potential VREF2 is output from the reference potential generating circuit B to the output potential monitor circuit 4.

The voltage divider circuit 6 includes a resistor 6a and a resistor 6b connected in series, and produces a monitor potential (VMONB). As illustrated in FIG. 5, one end of the resistor 6a is connected to an output end of the pump circuit 1, and one end of the resistor 6b is connected to a ground potential. The monitor potential VMONB is a potential at a junction of the resistor 6a and the resistor 6b.

The voltage divider circuit 7 includes a resistor 7a and a resistor 7b connected in series, and produces a monitor potential (VMONA). As illustrated in FIG. 5, one end of the resistor 7a is connected to the output end of the pump circuit 1, and one end of the resistor 7b is connected to the ground potential. The monitor potential VMONA is a potential at a junction of the resistor 7a and the resistor 7b.

It is to be noted that the resistance values of the resistors 6a, 6b, 7a and 7b are selected so that the monitor potential VMONB is greater than the monitor potential VMONA (i.e., VMONB>VMONA). Thus, in a process in which the output potential of the pump circuit 1 rises, a CLK cycle switch signal is generated before an enable signal is generated.

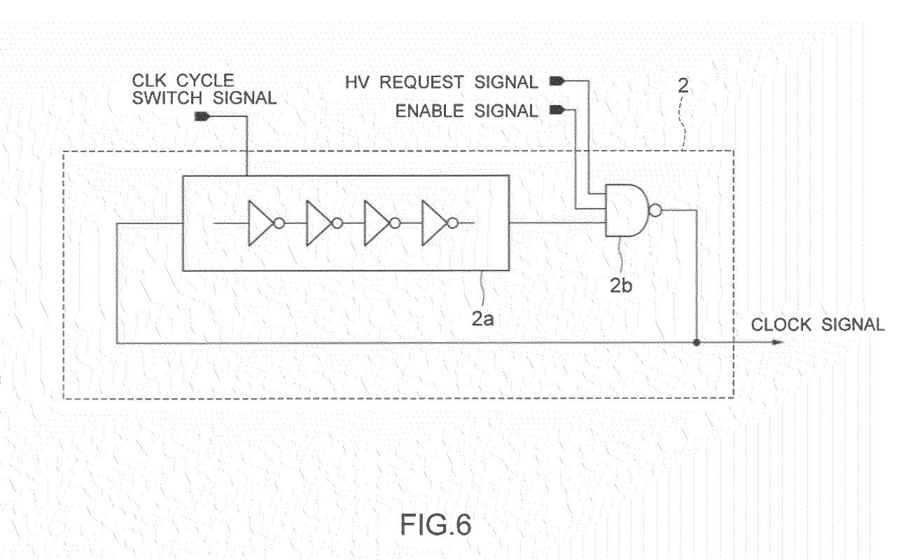

Next, a configuration example of the clock signal generating circuit 2 is described. FIG. 6 illustrates an exemplary configuration of the clock signal generating circuit 2.

As can be seen from FIG. 6, the clock signal generating circuit 2 includes a multi-stage inverter delay circuit 2a including an even number of inverters connected in series, and a NAND gate 2b. Each inverter included in the multi-stage inverter delay circuit 2a is configured to raise the operating speed upon receiving a CLK cycle switch signal. An HV request signal, an enable signal and an output of the multi-stage inverter delay circuit 2a are input to the NAND gate 2b. The NAND gate 2b functions as an inverter when receiving both an HV request signal and an enable signal. The output end of the NAND gate 2b is connected to the CLK terminal of the pump circuit 1 and the input terminal of the multi-stage inverter delay circuit 2a.

With the configuration mentioned above, when receiving both an HV request signal and an enable signal, the clock signal generating circuit 2 forms a ring oscillator including an odd number of inverters and outputs a clock signal. In other words, when not receiving at least one of the HV request signal and the enable signal, the clock signal generating circuit 2 does not output a clock signal regardless of whether the clock signal generating circuit 2 receives a CLK cycle switch signal. Regarding the frequency of a CLK signal to be output, in the case of not receiving a CLK cycle switch signal, the frequency of the clock signal is f1, whereas in the case of receiving a CLK cycle switch signal, the frequency of the clock signal is f2 (>f1).

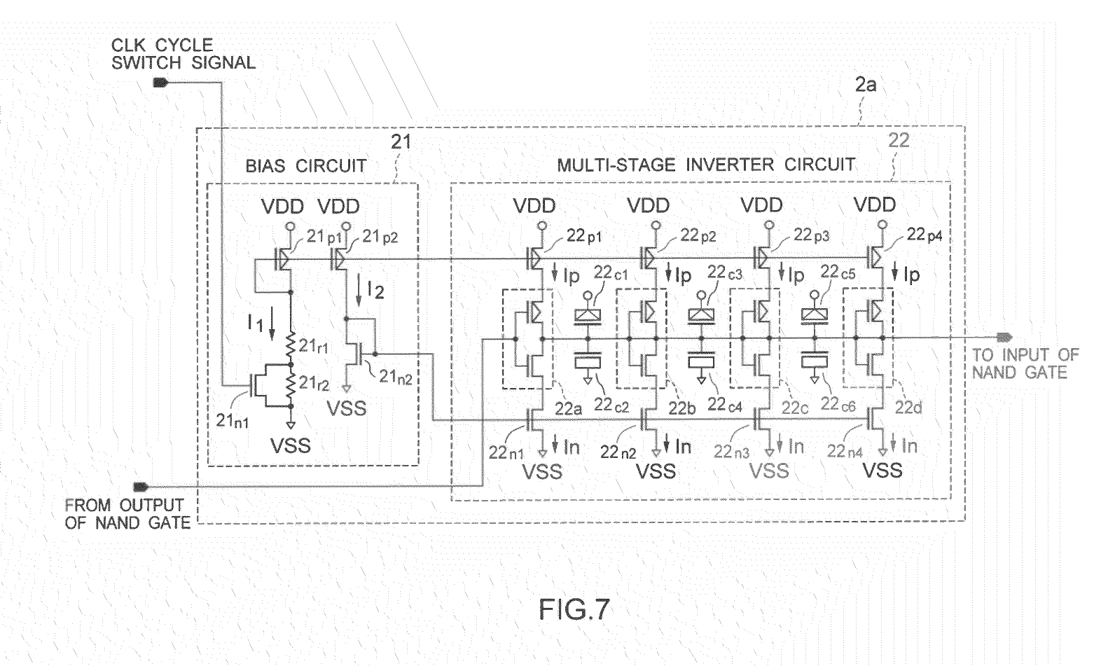

Next, a configuration example of the multi-stage inverter delay circuit 2a is described with reference to FIG. 7. As can be seen from FIG. 7, the multi-stage inverter delay circuit 2a includes a bias circuit 21 and a multi-stage inverter circuit 22.

The bias circuit 21 is made up of a PMOS transistor 21ₚ₁, a resistor 21ᵣ₁ and a resistor 21ᵣ₂ connected in series, and a PMOS transistor 21ₚ₂ and an NMOS transistor 21ₙ₂ connected in series. The bias circuit 21 operates as a current mirror circuit. As illustrated in FIG. 7, an NMOS transistor 21ₙ₁ is connected in parallel to the resistor 21ᵣ₂. The gate of the NMOS transistor 21ₙ₁ is connected to a terminal which receives a CLK cycle switch signal.

When a CLK cycle switch signal is input to the gate of the NMOS transistor 21ₙ₁, the resistor 21ᵣ₂ is short-circuited, and therefore a current I₁ flowing through the PMOS transistor 21ₚ₁ becomes larger. Therefore, a current 1₂ flowing through the PMOS transistor 21ₚ₂ also becomes larger.

As can be seen from FIG. 7, the multi-stage inverter circuit 22 includes four CMOS inverters 22a, 22b, 22c and 22d, four PMOS transistors 22ₚ₁ to 22ₚ₄ and four NMOS transistors 22ₙ₁ to 22ₙ₄, and six MOS capacitors 22_{c1}, 22_{c2}, 22_{c3}, 22_{c4}, 22_{c5} and 22_{c6}. An input terminal of the inverter 22a is connected to an output terminal of the NAND gate 2b. In addition, the output terminal of an inverter 22d is connected to an input terminal of the NAND gate 2b.

In this configuration example illustrated in FIG. 7, the MOS capacitors are provided between the respective individual inverters in order to decrease the operating speeds of the inverters, and further the PMOS transistors 22ₚ₁ to 22ₚ₄ and the NMOS transistors 22ₙ₁ to 22ₙ₄ are provided in order to limit a current flowing through the inverters.

In more detail, the PMOS transistor 22ₚ₁ is provided between the source of a PMOS transistor included in the CMOS inverter 22a and a power supply, and the NMOS transistor 22ₙ₁ is provided between the source of an NMOS transistor included in the CMOS inverter 22a and a ground potential. The PMOS transistor 22ₚ₁ and the NMOS transistor 22ₙ₁ are configured to limit a current flowing through the CMOS inverter 22a to adjust the operating speed of the inverter. Likewise, the PMOS transistors 22ₚ₂ to 22ₚ₄ and the NMOS transistors 22ₙ₂ to 22ₙ₄ are connected to the inverters 22b to 22d to adjust the operating speeds of the inverters 22b to 22d, respectively.

Next, the operation of the multi-stage inverter circuit 22 is described.

Upon receipt of a CLK cycle switch signal, the NMOS transistor 21ₙ₁ is turned on, and, as a result, only the resistor 21ᵣ₁ functions as a resistor between the drain of the PMOS transistor 21ₚ₁ and the ground potential VSS. A current I₁ flowing through the PMOS transistor 21ₚ₁ is given such that I₁=(VDD−Vth)/R. Here, VDD is a power supply voltage, Vth is a threshold voltage of the PMOS transistor 21ₚ₁, R is resistance between the drain of the PMOS transistor 21ₚ₁ and the ground potential VSS. Therefore, when a CLK cycle switch signal is received, the current I₁ and a current I₂ of the bias circuit 21 become larger. As a result, currents Iₚ and Iₙ flowing through the PMOS transistors 22ₚ₁ to 22ₚ₄ and the NMOS transistors 22ₙ₁ to 22ₙ₄ become larger to make the operating speeds of the inverters 22a to 22d faster. Accordingly, the oscillation frequency of the ring oscillator made up of the inverters 22a to 22d and the NAND gate 2b becomes larger. That is, the frequency of a clock signal output from the clock signal generating circuit 2 becomes larger.

Conversely, when not receiving a CLK cycle switch signal, the NMOS transistor 21ₙ₁ is off, and therefore the resistance R between the drain of the PMOS transistor 21ₚ₁ and the ground potential VSS is the sum of the resistance of the resistor 21ᵣ₁ and the resistance of the resistor 21ᵣ₂. Therefore, the currents I₁ and I₂ are small compared to the case of receiving a CLK cycle switch signal. Therefore, the currents Iₚ and Iₙ become smaller to make the operating speeds of the inverters 22a to 22d slower. Accordingly, the oscillation frequency of the ring oscillator is less than that in the case where a CLK cycle switch signal is received.

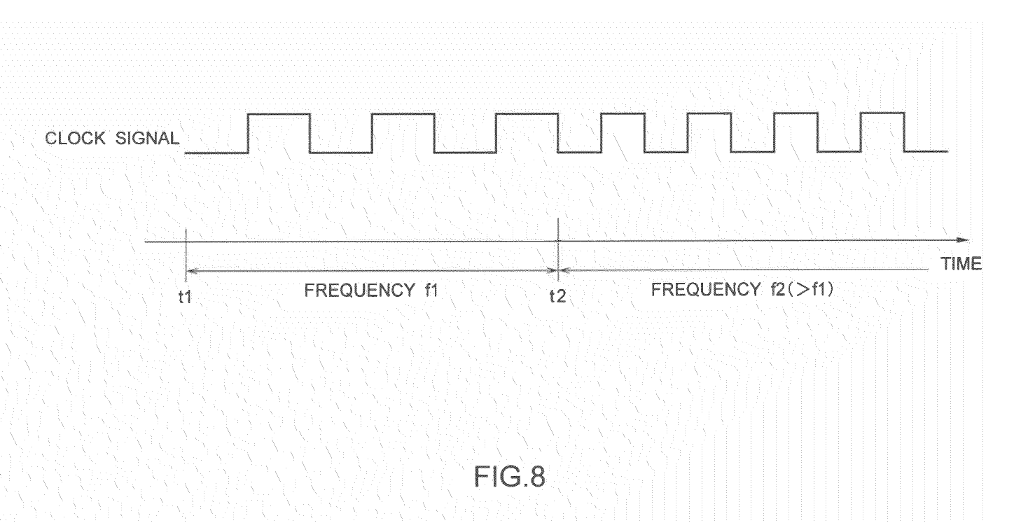

FIG. 8 illustrates waveforms of a clock signal input to the CLK terminal of the pump circuit 1. As can be seen from this figure, the frequency of the clock signal is the frequency f1 in a predetermined period from the start of boosting (a time t1), and is the frequency f2, which is greater than f1, in the subsequent period (at and after a time t2).

As described above, in this embodiment, the frequency of a clock signal input to the pump circuit is small in a predetermined period from the start of boosting, and the frequency of the clock signal is made large when the output potential reaches the predetermined potential. As a result, as can be seen from the relationship between current consumption and the frequency of a clock signal illustrated in FIG. 3, the peak of current consumption which appears at the beginning of the start of boosting can be reduced.

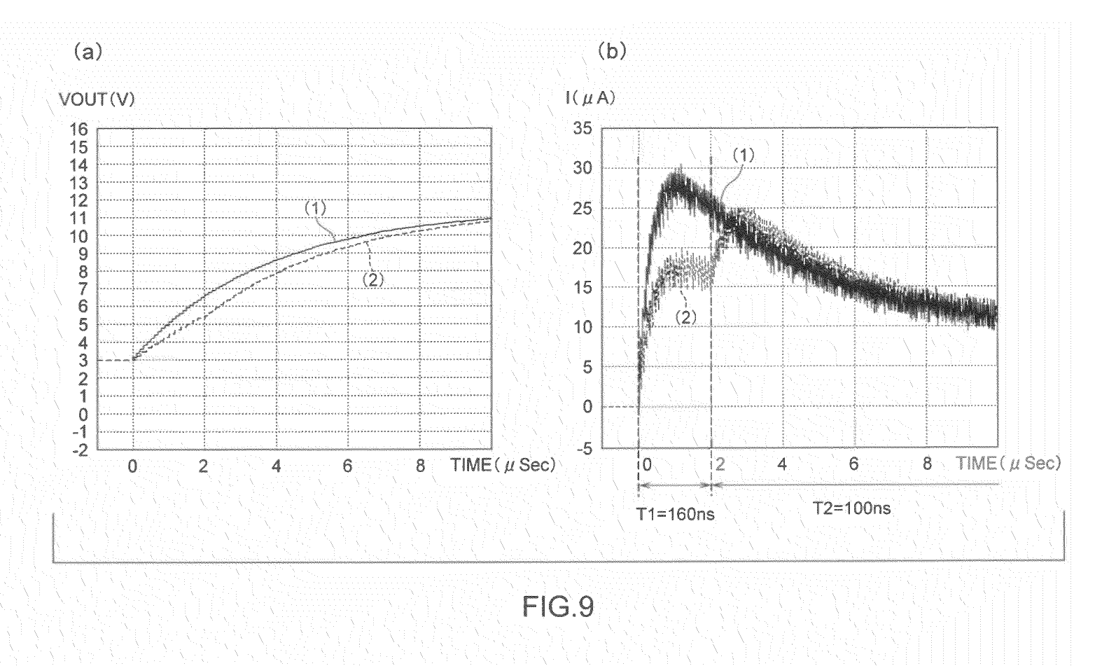

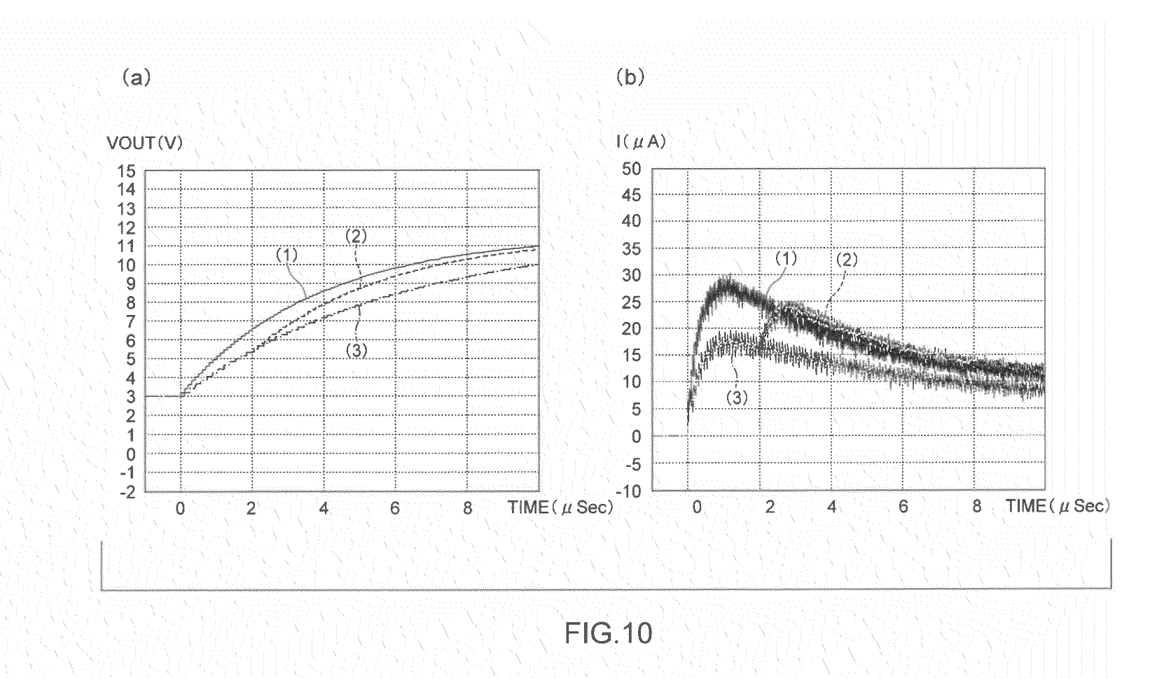

Operation simulation results of a semiconductor boost circuit according to this embodiment are described with reference to FIGS. 9(a) and 9(b) and FIGS. 10(a) and 10(b).

FIGS. 9(a) and 9(b) illustrate temporal waveforms (2) of the output potential VOUT and the current consumption I in the case where the cycle of a clock signal is 160 ns in a period of 2 μs from the start of boosting, and is 100 ns after that period. For the purpose of comparison, temporal waveforms (1) in the case where the cycle of a clock signal is kept at 100 ns after the start of boosting are additionally illustrated. As can be seen from FIGS. 9(a) and 9(b), compared to the case where the cycle of a clock signal is kept to 100 ns, the peak of current consumption is significantly reduced although the boosting speed slightly decreases under the influence of an increase in cycle of a clock signal.

In addition to the temporal waveforms (1) and (2) of the output potential and current consumption illustrated in FIGS. 9(a), 9(b), 10(a) and 10(b) illustrate temporal waveforms (3) in the case where the cycle of a clock signal is kept to 160 ns after the start of boosting, for the purpose of comparison. As can be seen from FIGS. 10(a) and 10(b), in the case where the cycle of a clock signal is kept to 160 ns from the start of boosting, the boosting speed significantly decreases although the peak of current consumption is further reduced.

As illustrated in FIGS. 9(a) and 9(b) and FIGS. 10(a) and 10(b), according to this embodiment, it is possible to significantly reduce the peak of current consumption compared to the case in which the frequency of a clock signal is kept high after the start of boosting. Further, a boosting time can be shortened compared to the case in which the cycle of a clock signal is kept low after the start of boosting. That is, according to this embodiment, it becomes possible to reduce the peak of current consumption significantly while avoiding an increase in time required for boosting a voltage as much as possible.

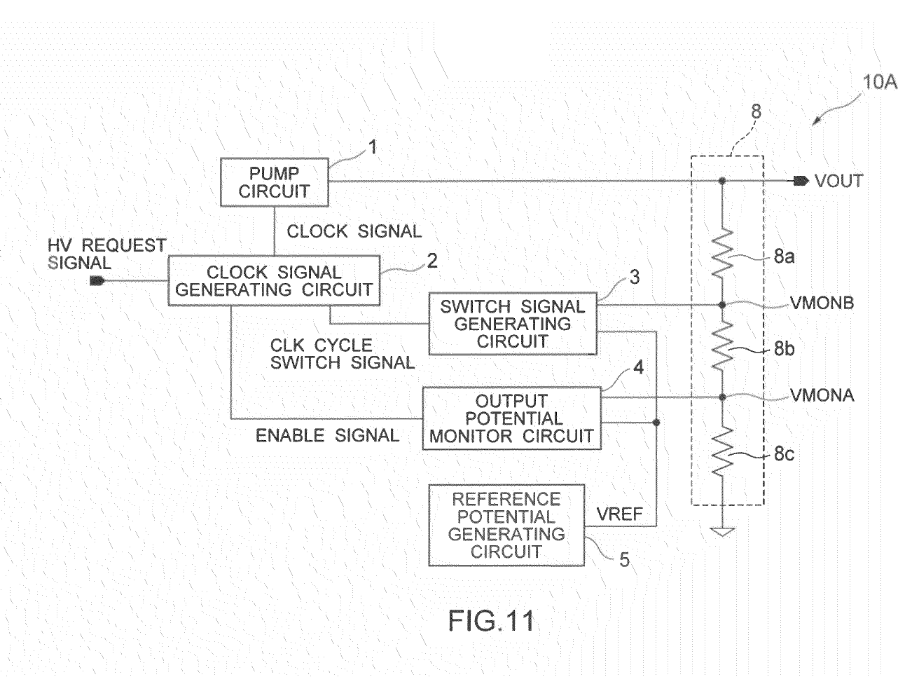

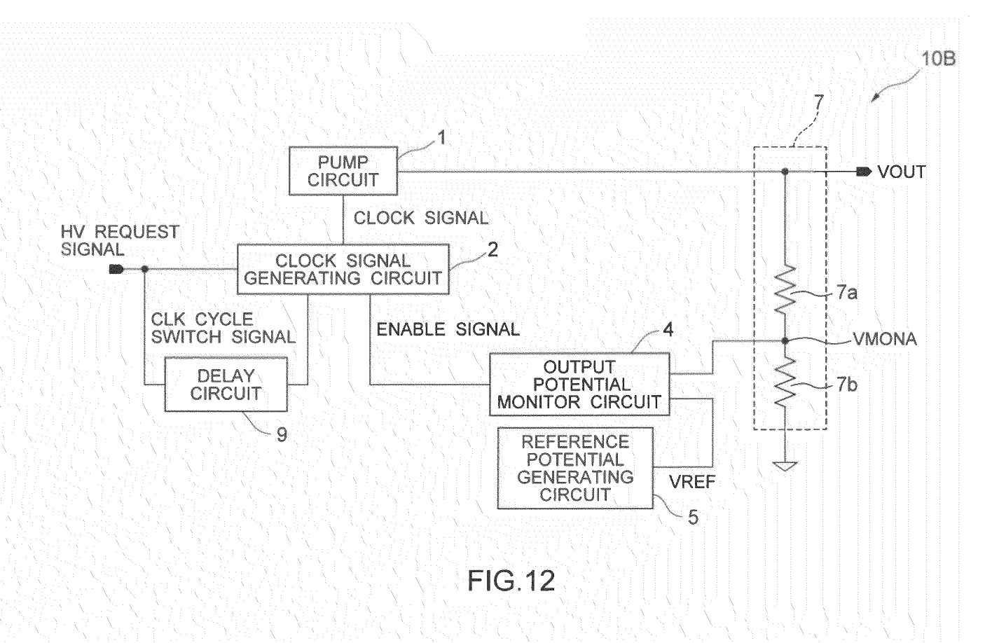

Next, with reference to FIGS. 11 and 12, a description is given of two modifications of a semiconductor boost circuit according to this embodiment.

FIG. 11 illustrates a configuration of a semiconductor boost circuit 10A according to a first modification. As can be seen from FIG. 11, in a semiconductor boost circuit 10A according to the first modification, the two voltage divider circuits 6 and 7 of the embodiment described above are unified into one voltage divider circuit 8. The voltage divider circuit 8 is used for both the switch signal generating circuit 3 and the output potential monitor circuit 4. The voltage divider circuit 8 is configured such that three resistors, that is, a resistor 8a, a resistor 8b and a resistor 8c are connected in series. The voltage divider circuit 8 produces two monitor potentials (VMONA and VMONB). As illustrated in FIG. 11, one end of the resistor 8a is connected to an output terminal of the pump circuit 1, and one end of the resistor 8c is connected to a ground potential. The monitor potential VMONB is a potential at a junction of the resistor 8a and the resistor 8b, and the monitor potential VMONA is a potential at a junction of the resistor 8b and the resistor 8c.

FIG. 12 illustrates a configuration of a semiconductor boost circuit 10B according to a second modification. As can be seen from FIG. 12, a semiconductor boost circuit 10B according to the second modification uses a delay circuit 9 as a switch signal generating circuit, instead of the switch signal generating circuit 3 and the voltage divider circuit 6, in order to generate a CLK cycle switch signal. The delay circuit 9 receives an HV request signal, and outputs the HV request signal as a CLK cycle switch signal after a predetermined time period has lapsed since receipt of the HV request signal. This predetermined time period (delay time) is selected as a value less than that of a time period required for an output potential of the pump circuit 1 to reach a set potential. For example, a time period required for an output potential to reach the above-described monitor potential VMONB is measured in advance, and the time period can be assumed as a delay time. It is to be noted that the delay circuit 9 may be configured as, for example, a digital circuit using a storage element, and may also be configured as an analog circuit using a CR time constant.

According to the first modification and the second modification, in addition to effects obtained by the foregoing embodiment, an effect of enabling the number of voltage divider circuits to be decreased to reduce the circuit size can be obtained.

Up to this point, the embodiment and two modifications of the invention have been described. In the foregoing description, the cycle of a clock signal is changed at two stages (f1→f2) in the boosting process of the pump circuit. However, the invention is not limited to this manner, and the cycle of the clock signal may be changed in three or more stages as long as a predetermined boosting time is satisfied. This enables the peak value of current consumption to be more reduced. As a result, occurrence of noise can further be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor boost circuit comprising:
a pump circuit configured to receive a clock signal and perform charge pump operation to boost an input potential to a set potential on the basis of the clock signal;
a switch signal generating circuit configured to output a CLK cycle switch signal when an output potential output by the pump circuit reaches a first potential greater than the input potential and less than the set potential; and
a clock signal generating circuit configured to output the clock signal having a first frequency if not receiving the CLK cycle switch signal, and output the clock signal having a second frequency greater than the first frequency if receiving the CLK cycle switch signal.

2. The semiconductor boost circuit of claim 1, further comprising:
a first voltage divider circuit configured to divide the output potential to produce a first monitor potential,
wherein the switch signal generating circuit compares the first monitor potential to a first reference potential, and outputs the CLK cycle switch signal in a case where the first monitor potential as the output potential is greater than the first reference potential as the first potential.

3. The semiconductor boost circuit of claim 2, wherein the first voltage divider circuit
comprises a first resistor and a second resistor connected in series, the first resistor including one end connected to an output terminal of the pump circuit, and the second resistor including one end grounded, and
outputs, as the first monitor potential, a potential at a junction of the first resistor and the second resistor.

4. The semiconductor boost circuit of claim 2, further comprising:
a second voltage divider circuit configured to divide the output potential to produce a second monitor potential; and
an output potential monitor circuit configured to compare the second monitor potential to a second reference potential, to output an enable signal required for the clock signal generating circuit to output the clock signal in a case where the second monitor potential is less than the second reference potential.

5. The semiconductor boost circuit of claim 4, wherein the second voltage divider circuit
comprises a first resistor and a second resistor connected in series, the first resistor including one end connected to an output terminal of the pump circuit, and the second resistor including one end grounded, and
outputs, as the second monitor potential, a potential at a junction of the first resistor and the second resistor.

6. The semiconductor boost circuit of claim 2, wherein the clock signal generating circuit comprises:
a multi-stage inverter delay circuit including an even number of inverters connected in series, each of the inverters being configured to raise an operating speed on the basis of the CLK cycle switch signal; and
a NAND gate configured to receive a high potential output request signal requesting the set potential, an enable signal and an output of the multi-stage inverter delay circuit, and to operate as an inverter when receiving both the high potential output request signal and the enable signal, the NAND gate including an output end configured to output the clock signal, the output end being connected to the pump circuit and an input terminal of the multi-stage inverter delay circuit.

7. The semiconductor boost circuit of claim 6, wherein the pump circuit includes:
first to N-th MOS transistors connected in series and each of the first to N-th MOS transistors is a diode-connected configuration;
first capacitors including one ends connected to nodes between the (2i−1)-th (i: natural number) MOS transistors and the 2i-th MOS transistors, and the other ends connected to an output end of a first inverter configured to receive the clock signal; and
second capacitors including one ends connected to nodes between the 2i-th MOS transistors and the (2i+1)-th MOS transistors, and the other ends connected to an output end of a second inverter configured to receive an output of the first inverter.

8. The semiconductor boost circuit of claim 1, further comprising:
a voltage divider circuit configured to divide the output potential to produce a first monitor potential and a second monitor potential less than the first monitor potential; and
an output potential monitor circuit configured to compare the second monitor potential to a reference potential, to output an enable signal required for the clock signal generating circuit to output the clock signal in a case where the second monitor potential is less than the reference potential,
wherein the switch signal generating circuit compares the first monitor potential to the reference potential, and outputs the CLK cycle switch signal in a case where the first monitor potential as the output potential is greater than the reference potential as the first potential.

9. The semiconductor boost circuit of claim 8, wherein the voltage divider circuit
comprises a first resistor, a second resistor and a third resistor connected in series, the first resistor including one end connected to an output terminal of the pump circuit, and the third resistor including one end grounded, and
outputs, as the first monitor potential, a potential at a junction of the first resistor and the second resistor, and outputs, as the second monitor potential, a potential at a junction of the second resistor and the third resistor.

10. The semiconductor boost circuit of claim 8, wherein the clock signal generating circuit includes:
a multi-stage inverter delay circuit including an even number of inverters connected in series, each of the inverters being configured to raise an operating speed on the basis of the CLK cycle switch signal; and
a NAND gate configured to receive a high potential output request signal requesting the set potential, an enable signal and an output of the multi-stage inverter delay circuit, and to operate as an inverter when receiving both the high potential output request signal and the enable signal, the NAND gate including an output end configured to output the clock signal, the output end being connected to the pump circuit and an input terminal of the multi-stage inverter delay circuit.

11. The semiconductor boost circuit of claim 10, wherein the pump circuit includes:
first to N-th MOS transistors connected in series and each of the first to N-th MOS transistors is a diode-connected configuration;
first capacitors including one ends connected to nodes between the (2i−1)-th (i: natural number) MOS transistors and the 2i-th MOS transistors, and the other ends connected to an output end of a first inverter configured to receive the clock signal; and
second capacitors including one ends connected to nodes between the 2i-th MOS transistors and the (2i+1)-th MOS transistors, and the other ends connected to an output end of a second inverter configured to receive an output of the first inverter.

12. The semiconductor boost circuit of claim 1, further comprising:
a voltage divider circuit configured to divide the output potential to produce a monitor potential; and
an output potential monitor circuit configured to compare the monitor potential to a reference potential, to output an enable signal required for the clock signal generating circuit to output the clock signal in a case where the monitor potential is less than the reference potential.

13. The semiconductor boost circuit of claim 12, wherein the voltage divider circuit
comprises a first resistor and a second resistor connected in series, the first resistor including one end connected to an output terminal of the pump circuit, and the second resistor including one end grounded, and
outputs, as the monitor potential, a potential at a junction of the first resistor and the second resistor.

14. A semiconductor boost circuit comprising:
a pump circuit configured to receive a clock signal and perform charge pump operation to boost an input potential to a set potential on the basis of the clock signal;
a delay circuit configured to receive a high potential output request signal requesting the set potential, and output the high potential output request signal as a CLK cycle switch signal upon a lapse of a predetermined time period since receipt of the high potential output request signal; and
a clock signal generating circuit configured to output the clock signal having a first frequency upon receipt of the high potential output request signal, and output the clock signal having a second frequency greater than the first frequency upon receipt of the CLK cycle switch signal.

15. The semiconductor boost circuit of claim 14, further comprising:
a voltage divider circuit configured to divide an output potential output by the pump circuit to produce a monitor potential; and
an output potential monitor circuit configured to compare the monitor potential to a reference potential, to output an enable signal required for the clock signal generating circuit to output the clock signal in a case where the monitor potential is less than the reference potential.

16. The semiconductor boost circuit of claim 15, wherein the voltage divider circuit
comprises a first resistor and a second resistor connected in series, the first resistor including one end connected to an output terminal of the pump circuit, and the second resistor including one end grounded, and
outputs, as the monitor potential, a potential at a junction of the first resistor and the second resistor.

17. The semiconductor boost circuit of claim 14, wherein the clock signal generating circuit includes:
a multi-stage inverter delay circuit including an even number of inverters connected in series, each of the inverters being configured to raise an operating speed on the basis of the CLK cycle switch signal; and
a NAND gate configured to receive the high potential output request signal, an enable signal and an output of the multi-stage inverter delay circuit, and to operate as an inverter when receiving both the high potential output request signal and the enable signal, the NAND gate including an output end configured to output the clock signal, the output end being connected to the pump circuit and an input terminal of the multi-stage inverter delay circuit.

18. A method of controlling a semiconductor boost circuit including a clock signal generating circuit configured to output a clock signal, and a pump circuit configured to perform charge pump operation on the basis of the clock signal to boost an input potential to a set potential, the method comprising:
monitoring an output potential output by the pump circuit;
controlling the clock signal generating circuit so that the clock signal generating circuit outputs the clock signal having a first frequency to the pump circuit until the output potential reaches a predetermined potential greater than the input potential and less than the set potential; and
controlling the clock signal generating circuit so that the clock signal generating circuit outputs to the pump circuit the clock signal having a second frequency greater than the first frequency when the output potential reaches the predetermined potential.

19. The method of controlling a semiconductor boost circuit of claim 18, wherein
the output potential is monitored using a voltage divider circuit configured to divide the output potential, and
whether the output potential reaches the predetermined potential is determined by comparing the output potential monitored in the voltage divider circuit to a reference voltage.

20. The method of controlling a semiconductor boost circuit of claim 18, wherein
the clock signal generating circuit is controlled so that the clock signal generating circuit does not output the clock signal when the output potential reaches the set potential.
